(19) United States
(12) Patent Application Publication
(10) Pub. No.: US 2024/0021677 A1
(43) Pub. Date: Jan. 18, 2024

(54) PACKAGED STRUCTURES FOR LATERAL HIGH VOLTAGE GALLIUM NITRIDE DEVICES

(71) Applicant: GaNPower international Inc., Vancouver (CA)

(72) Inventors: Zhanming LI, West Vancouver (CA); Zeyu WAN, Vancouver (CA)

(21) Appl. No.: 18/363,873

(22) Filed: Aug. 2, 2023

Related U.S. Application Data
(60) Provisional application No. 63/394,794, filed on Aug. 3, 2022.

(51) Int. Cl. H01L 29/20; H01L 29/778; H01L 29/08; H01L 23/495

(52) U.S. Cl. CPC H01L 29/2003; H01L 29/7787; H01L 29/7783; H01L 29/0865; H01L 29/0882; H01L 23/49562; H01L 23/49575

(57) ABSTRACT

Packaging structures for lateral high voltage gallium nitride (GaN) devices achieve electrical isolation while also maintaining thermal dissipation is provided. The electrical isolation reduces or eliminates vertical leakage current, improving high voltage performance with the semi-insulating layer for adhering the lateral semiconductor power device chip to the back-plate. The packages may use or be compatible standards such as JEDEC, which reduces packaging cost and facilitates implementation of the packaged devices in conventional circuit design approaches.

### CROSS REFERENCE TO RELATED APPLICATION

This patent application claims the benefit and priority of US provisional application of U.S. 63/394,794 with a filing date of Aug. 3, 2022, the disclosure of which is incorporated by reference herein in its entirety as part of the present application.

### TECHNICAL FIELD

The invention relates to packaging of lateral power electronic devices. More specifically, the invention relates to packaging of lateral power electronic devices that reduces or eliminates vertical leakage current.

### BACKGROUND ART

Gallium nitride (GaN) power electronic devices feature favourable performance characteristics such as high efficiency and high power density, and are expected to replace silicon (Si) and silicon carbide (SiC) as the dominant power devices. One particular technology of great promise is GaN grown on a silicon substrate (GaN/Si), which offers superior performance with low cost.

However, power device implementations using GaN/Si face a number of limitations. One is that the silicon substrate is of p-minus doping and cannot sustain high voltage, particularly in the vertical direction (i.e., perpendicular to the plane of the device die). This is evident as substrate leakage when the voltage is high (e.g., greater than 1,000 V).

Another limitation is that GaN/Si power devices are lateral devices in which electrodes (e.g., gate, drain, source of a field-effect transistor (FET)) are arranged on the same side (e.g., the top) of the device, and current flows laterally across the device between electrodes. As such, conventional packaging formats that are typically intended for use with vertical devices in which electrodes are arranged on opposite sides (e.g., the top and bottom) of the device, and current flows vertically through the device, cannot be used.

### SUMMARY

According to one aspect of the invention there is provided a packaged semiconductor device, which includes a lateral semiconductor power device chip including an upper surface having at least two electrodes disposed thereon, and a lower surface, at least one metal lead electrically connected to a first electrode of the at least two electrodes; a back-plate; and a semi-conductive adhesive layer disposed between the lower surface of the lateral semiconductor power device chip and the back-plate. The back-plate includes at least a metal portion that is electrically connected to a second electrode of the at least two electrodes.

In accordance with the above aspects, in one embodiment the back-plate includes only the metal portion and underlies the lateral semiconductor power device chip.

In accordance with the above aspects, in one embodiment the electrically insulating and thermally conducting portion of the back-plate has an area larger than or equal to an area of the lateral semiconductor power device chip.

Further, in one embodiment the back-plate includes a metal portion and a semi conductive adhesive portion disposed adjacent the metal portion.

In accordance with the above aspects, in one embodiment the lateral semiconductor power device chip is a field-effect transistor (FET); wherein the first electrode is a gate electrode and is electrically connected to a first metal lead; wherein the second electrode is a source electrode and is electrically connected to the metal portion of the back-plate; wherein a third electrode is a drain electrode and is electrically connected to a second metal lead.

In accordance with the above aspects, in one embodiment the lateral semiconductor power device chip is an FET. The first electrode is a gate electrode and is electrically connected to a first metal lead. The second electrode is a drain electrode and is electrically connected to the metal portion of the back-plate. A third electrode is a source electrode and is electrically connected to a second metal lead.

In accordance with the above aspects, in various embodiments the lateral semiconductor power device chip includes a GaN, GaN/GaN, GaN/Si, or GaN/ceramic technology.

In accordance with the above aspects, the package may conform with a JEDEC standard format.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In order to explain the embodiments of the present disclosure or the technical solutions in the prior art more clearly, the following drawings that need to be used in the description of the embodiments or the prior art are briefly introduced. Obviously, the drawings in the following description are only embodiments of the present disclosure. For those of ordinary skill in the art, other drawings can be obtained based on the drawings disclosed without creative work.

FIG. 1 is a discrete silicon or silicon-carbide power FET package of prior art;

FIG. 2 is a discrete GaN power FET package of prior art.

FIG. 3 is another discrete GaN power FET package with insulating adhesive glue.

FIG. 4 is an FET turn-on experimental data for GaNFET samples packaged using insulating adhesive glue.

FIG. 5 is an analysis of abnormal dynamic after-turn-on behavior.

FIG. 6 is an embodiment of GaN chip packaging of the present disclosure.

FIG. 7 Two embodiments of this invention for using a semi-insulating adhesive glue for a GaNFET rated at 1200V. Wherein the line 701 indicates that the current leaks through the adhesive glue with constant resistance while the line 702 is another embodiment where current saturates at above 1000V.

FIG. 8 is another embodiment of the invention for GaN chip.

FIG. 9 is an embodiment of the invention for GaN chip packaging that uses conductive adhesive glue and partial semi-insulating back-plate.

FIG. 10 is an embodiment of the invention for GaN chip packaging that uses conductive adhesive glue and partial semi-insulating back-plate that is directly in contact with the PCB at the bottom.

FIG. 11 is another embodiment of the invention for GaN chip packaging that uses conductive adhesive glue on a GaN/Si chip that is treated with ion implantation isolation before adheresion to the conductive backplate.

### DETAILED DESCRIPTION OF THE EMBODIMENTS

Technical solutions of the present disclosure will be clearly and completely described below with reference to the embodiments. Obviously, the described embodiments are only part of the embodiments of the present disclosure, not all of them. Based on the embodiments of the disclosure, all other embodiments made by those skilled in the art without sparing any creative effort should fall within the protection scope of the disclosure.

Described herein are packaging structures and related methods for lateral power electronic devices based on, but not limited to, GaN, GaN/GaN, GaN/Si, and GaN/ceramic technologies. Examples of power devices include, but are not limited to, transistors (e.g., field-effect transistors (FETs)) and diodes. Embodiments overcome limitations of prior approaches to packaging such devices.

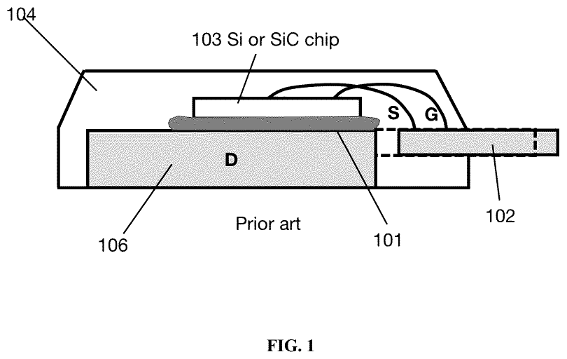

FIGS. 1-3 show prior packaging structures typically used for discreet silicon and silicon carbide power devices or GaN power FET packaging structures. The semiconductor chip is a vertical device, that is, electrodes are disposed on opposed planar surfaces (i.e., the gate G and source S electrodes are disposed on the top surface and the drain electrode is disposed on the bottom surface, based on the orientation shown in FIG. 1) and current flows vertically with respect to the plane of the chip. Many device package formats (e.g., JEDEC standards such as TO220, TO252, TO263) are based on such an arrangement. As shown in FIGS. 1, the semiconductor chip 103 is adhered to a metal back-plate 106 of the package with an electrically conductive adhesive glue 101. Thus, when the chip is adhered to the back-plate 106, the back-plate becomes the drain electrode. The source and gate electrodes are wire-bonded, respectively, to metal leads 102 (shown in FIG. 1 for clarity). Some package formats may provide a metal lead connected to the metal back-plate 106. When used in an external circuit, the package may be soldered to a circuit board via the metal back-plate 106 and metal leads 102. Other metal leads, if included, may also be attached to the circuit board, and optionally it may be wire-bonded to one of the device electrodes, depending on the circuit design, or it may be removed. The packaged device is covered with a molded polymer encapsulant 104 that provides access to the metal contacts.

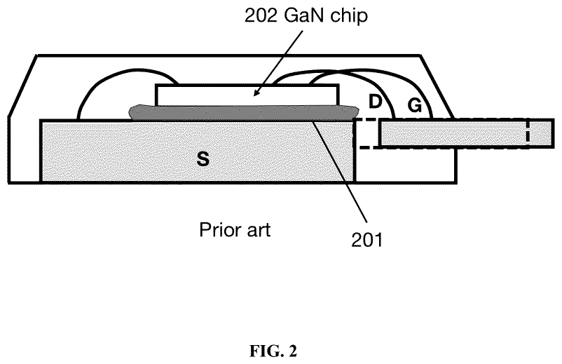

FIG. 2 shows a prior packaging structure for a GaN chip 202. In this approach an electrically conductive adhesive glue 201 as in the prior approach of FIG. 1 is used to attach the GaN chip 203 on a package metal frame such as that commonly available in JEDEC standards. However, since the GaN chip is a lateral device, the source S electrode is on the top surface of the device and is wire-bonded to the back-plate. The drain D and gate G electrodes are also on the top surface of the device and are wire-bonded, respectively, to metal leads. Some package formats may provide a metal lead connected to the metal back-plate. The packaged device is covered with a molded polymer encapsulant that provides access to the metal contacts.

There are limitations to the approach as above. The first limitation is that those approach enables vertical current flow through the device (i.e., current flow perpendicular to the plane of the device die), which is undesirable for lateral devices, and the problem is exacerbated under high power, high voltage (e.g., 1,000 V and greater) where the vertical current is evident as substrate leakage. Another limitation is that designating the back-plate 106 as the source electrode renders many of the JEDEC standard packaging frames, such as TO263-7, incompatible, since these JEDEC standard frames are designed with the drain connected to the back-plate.

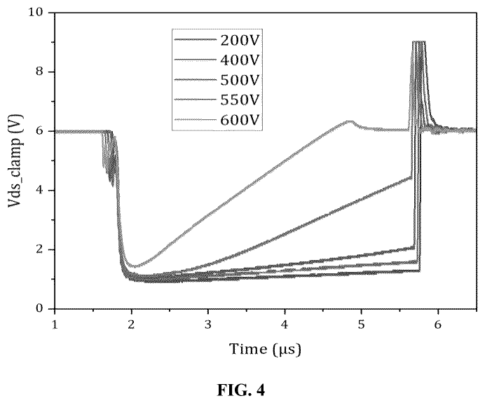

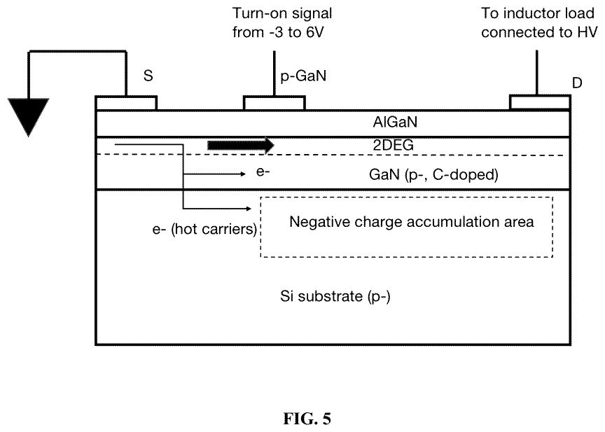

The vertical leakage current and abnormal after-turn-on dynamic behavior under higher currents and higher voltages can be explained by considering the structure of a GaNFET samples. An example is shown in FIGS. 4-5. The device, which may be of a thickness in the the range of 200-400 μm, includes a two-dimensional electron gas (2DEG) structure based on GaN/AlGaN layers disposed on a silicon substrate. Source S, gate G, and drain D electrodes are disposed on the top surface of the chip. Due to the large difference between lateral electrode spacing and substrate thickness, the electric field within the silicon substrate 302 (P doped) is mostly a vertical field. Such vertical field promotes the undesirable vertical substrate leakage. Since the prior approach, shown in FIG. 4, of using conductive adhesive 201 does not prevent the vertical leakage current, and may facilitate the vertical leakage current, the breakdown voltage of the device structure is significantly limited and such an approach is unsuitable for high power lateral devices.

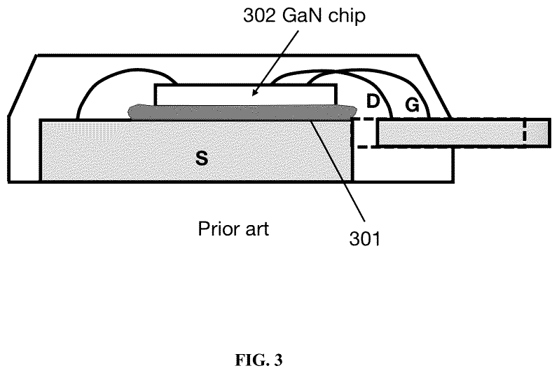

In FIG. 3, an insulating adhesive glue 301 that completely blocked the substrate leakage and enabled high breakdown voltages for lateral GaNFET in various packaging forms.

However, use of complete insulation caused issues in dynamic behavior in high speed switching. As is indicated in FIG. 4 in a double pulse testing (DPT) experiment where the device under test (DUT) is loaded with an inductor which is discharged using a high voltage diode. Experimental data indicates that high current and high voltage caused on-state of the GaNFET packaged using insulating adhesive to exhibit a surge of high dynamic on-resistance which would take a long time to recover.

An explanation of the abnormal dynamic behavior (as is shown in FIG. 5) is that when the substrate is completely insulated from the backplate without electrically connection, its potential can be easily influenced by any carrier injection from the 2DEG during fast turn on. The bulk GaN material below the 2DEG is usually p-type doped (C-doped) and this forms a potential barrier to prevent injection of electrons from 2DEG in steady state. However, during fast turn-on process, the high dV/dt causes sudden acceleration of electron from the source contact towards the drain and some of the carriers would gain high kinetic energy to overcome the C-doped barrier. Should the silicon substrate be grounded, injected hot carriers would have been leaked towards the backplate without being accumulated in the substrate area.

Accumulation of electrons in C-doped GaN and the substrate would form a negatively charged area below the 2DEG. The negative space charge area which become a virtual bottom gate with transient negative bias to deplete the carriers in the 2DEG layer inducing a transient increase in dynamic Rds at high voltage and high current.

In the below descriptions of embodiments an FET is used as an example of a lateral GaN power device, wherein the electrodes (gate, drain, and source) are disposed on the top surface of the device. It will be understood that other lateral GaN power devices may be used, such as diodes, wherein the electrodes (anode and cathode) are disposed on the top surface of the device.

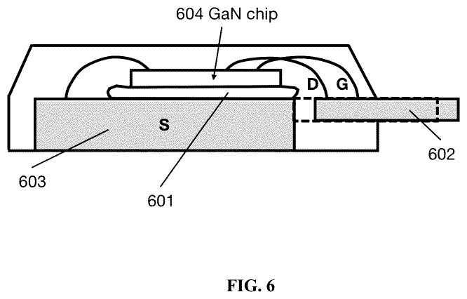

A device packaging structure according to one embodiment of the invention shown in FIG. 6. Referring to FIG. 6, a GaN device chip 604, including, e.g., a GaN grown on silicon substrate (i.e., GaN/Si), is adhered to a back-plate using a semi-insulating adhesive layer 601. The semi-insulating adhesive layer 601 may be a semi-insulating adhesive and yet thermally conducting glue for adhering the GaN chip in it's packaging frame. In this embodiment the back-plate is made entirely of metal. The source S electrode of the device 603 is wire-bonded to the metal back-plate. The drain D and gate G electrodes of the device are wire-bonded, respectively, to metal leads of the package (shown offset in FIG. 6 for clarity). Some embodiments may include a package format with a metal lead connected to the metal back-plate. When used in an external circuit, the package may be soldered to a circuit board via the metal back-plate and metal leads. The metal lead, if included, may also be attached to the circuit board, and optionally it may be wire-bonded to one of the device electrodes, depending on the circuit design, or it may be removed. The packaged device is covered with a molded polymer encapsulant that provides access to the metal contacts. The semi-insulating adhesive layer 601 absorbs at least some of the voltage drop from the power device substrate, and thus prevents, limits, or substantially reduces substrate vertical leakage current.

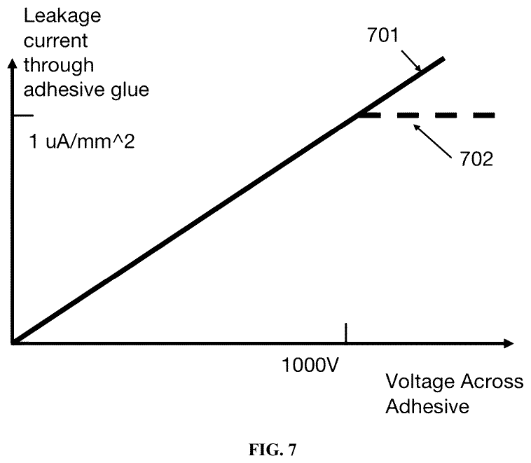

The electrical conduction of the glue is such that approximately one micro ampere per mm squared GaN chip would leak through the glue area at 1000V (as is shown in FIG. 7). For a typical glue thickness of 0.2 mm, the electrical resistance of the glue would be 0.5e9 Ohm-cm.

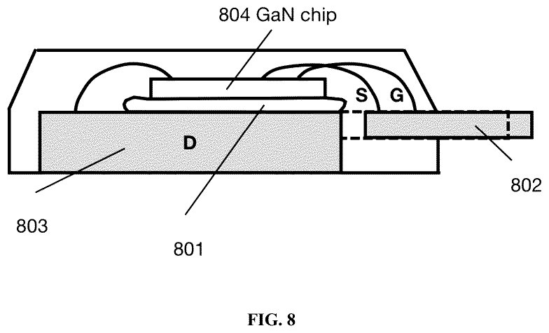

In another embodiment, shown in FIG. 8, the packaging structure is substantially the same as that shown in the embodiment of FIG. 6, wherein a GaN device chip 804, including, e.g., a GaN grown on silicon substrate (i.e., GaN/Si), is adhered to a metal back-plate using a semi-insulating adhesive and yet thermally conducting glue 801. However, in this embodiment the drain D electrode of the device 803 is wire-bonded to the back-plate. The source S and gate G electrodes of the device are wire-bonded, respectively, to metal leads. Some embodiments may include a package format with a metal lead connected to the metal back-plate. In various embodiments, the gate metal lead may optionally be electrically connected to the drain metal lead or to the back-plate, or to the metal lead, if provided, depending on the specific device configuration. The packaged device is covered with a molded polymer encapsulant 504 that provides access to the metal contacts. According to this embodiment, in addition to preventing, limiting, or substantially reducing substrate vertical leakage current, another benefit is that the configuration of the drain located at the bottom of the structure allows use of a standard JEDEC frame, such as TO263-7, which reduces packaging cost and makes the structure more user-friendly since it facilitates implementation in conventional circuit design approaches.

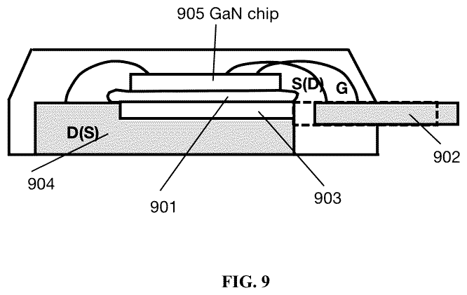

Another embodiment is shown in FIG. 9. In this embodiment, the back-plate comprises a metal portion 904 and a semi-insulting (but thermally conducting) portion 903 such as special types of ceramics with sheet resistance about 1e10 ohm/square. According to this embodiment, a GaN device chip 603, including, e.g., a GaN/Si, is adhered to the semi-insulting portion 903. The material 903 may be a ceramic material such as, for example, aluminum nitride (AlN), which has a high thermal conductivity and is an electrical insulator. The semi-insulting portion 903 may have a thickness that is similar to or less than the thickness of the chip 603, such as, for example, at least 100 μm thick. The ceramic semi-insulting portion 903 is disposed on the metal portion 904 of the back-plate. In this embodiment, the drain D or source S electrode of the device is wire-bonded to the metal back-plate. The other of the source S or drain D electrode, and the gate G electrode of the device are wire-bonded, respectively, to metal leads. Some embodiments may include a package format with a metal lead connected to the metal portion 904 of the back-plate. In various embodiments, the gate metal lead may optionally be electrically connected to the metal back-plate or the metal lead, or the metal lead, if provided, depending on the specific device configuration. As shown in FIG. 9, the semi-insulting portion 903 is beneath the semiconductor chip 905 and has an area larger than or equal to an area occupied by the semiconductor chip 905. The lower portion of the back-plate 606a is metal so that maximum electrical and thermal conduction can be achieved through the back-plate to a circuit board (e.g., a printed circuit board (PCB)) on which it may be mounted. The packaged device is covered with a molded polymer encapsulant that provides access to the metal contacts. The partial ceramic structure of this embodiment is suitable for large packaging formats, such as, for example, JEDEC TO263-7. An advantage of this structure is that the insulating semi-insulting portion 903 provides additional blocking of high voltage and further reduction or elimination of substrate vertical leakage current. The structure is such that bottom of the whole back-plate is still of metal so that maximum electrical and thermal conduction can be achieved. Since the ceramic resistance and thickness is easier to control than glue adhesives, this type of packaging can achieve improved accuracy. In this embodiment, conductive glue would be used and there is no need to control the glue thickness.

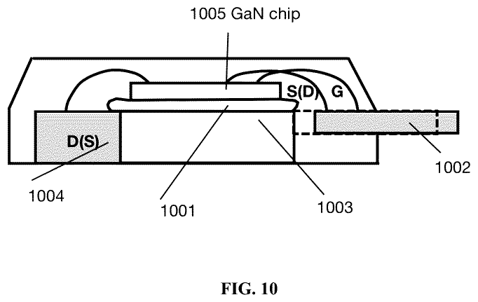

Another embodiment is shown in FIG. 10. In this embodiment, the back-plate comprises a metal portion 1004 and a semi-insulting (but thermally conducting) portion 1003 such as special types of ceramics with sheet resistance about 1e10 ohm/square. According to this embodiment, a GaN device chip 1005, comprising, e.g., GaN/Si, is adhered to the semi-insulting portion 1003. The material of the semi-insulting (but thermally conducting) portion 1003 may be a ceramic material such as AlN. Unlike the embodiment of FIG. 9, in this embodiment the semi-insulting portion 1003 has a thickness that extends all the way to the bottom of the package, so that it is in contact with a circuit board (e.g., a PCB) on which the package may be mounted. The semi-insulting portion 1003 is beneath the semiconductor chip and may have an area larger than or equal to an area occupied by the semiconductor chip 1005. The embodiment includes a metal portion 1004 of the back-plate that is disposed adjacent the semi-insulting portion 1003, and may be adhered to the semi-insulting portion 1003. The metal back-plate provides an electrical connection to the PCB on which the package is mounted from the device drain D or source S. The drain or source electrode of the device is wire-bonded to the metal portion of the back-plate. The other of the source or drain electrode and the gate G electrode of the device are wire-bonded, respectively, to metal leads. Some embodiments may include a package format with a metal lead, which may be connected to the metal portion 1004 of the back-plate, or may be floating. In the latter case, the metal lead may be connected to a selected one of the electrodes using wire bonding, depending on the specific device configuration. In various embodiments, the gate metal lead may optionally be electrically connected to the metal lead or the back-plate, depending on the specific device configuration. The packaged device is covered with a molded polymer encapsulant that provides access to the metal contacts. This embodiment is suitable for smaller package formats such as a lead frame-based package (e.g., quad flat no-leads (QFN), chip scale package (CSP)) where the semi-insulting portion 1003 can serve as creepage distance spacing. Advantageously, the semi-insulting portion 1003 provides additional blocking of high voltage and further reduction or elimination of substrate vertical leakage current.

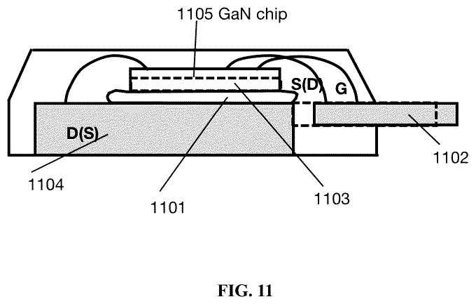

FIG. 11 is another preferred embodiment of the invention similar to the embodiment in FIGS. 9 and 10 except the chip 1105 is treated with isolation ion implanation to control the sheet resistance to the order of 1e10 Ohm/square (shown with the dotted box 1103). Since the semi-insulation is done by ion implanation isolation on the back of the die already (functioning as the semi-insulting portions in the embodiments above), conductive glue 1101 would be used and there is no need to control the glue thickness.

The above description of the disclosed embodiments enables those skilled in the art to realize or use the present disclosure. Many modifications to these embodiments will be apparent to those skilled in the art. The general principle defined herein can be realized in other embodiments without departing from the spirit or scope of the present disclosure. Therefore, the present disclosure will not be limited to these embodiments shown herein, but will conform to the widest scope consistent with the principle and novel features disclosed herein.

What is claimed is:

1. A packaged semiconductor device, comprising:
a lateral semiconductor power device chip comprising an upper surface having at least two electrodes disposed thereon and a lower surface;
at least one metal lead electrically connected to a first electrode of the at least two electrodes;
a back-plate disposed underneath the lower surface of the chip; and
a semi-insulating layer configured to adhere the lateral semiconductor power device chip to the back-plate;
wherein the back-plate comprises at least a metal portion that is electrically connected to a second electrode of the at least two electrodes; and
an electrical resistivity of the semi-insulating layer ranges from 1e4 to 1e10 Ohm/mm\hat{ }2.

2. The packaged semiconductor device of claim 1, wherein the back-plate comprises only a metal portion and underlies the lateral semiconductor power device chip.

3. The packaged semiconductor device of claim 1, wherein the back-plate comprises the metal portion and semi-insulting portion disposed adjacent the metal portion; wherein the lateral semiconductor power device chip is disposed over the semi-insulting portion of the back-plate; wherein the semi-insulting portion is disposed between the lateral semiconductor power device chip and the back-plate.

4. The packaged semiconductor device of claim 3, wherein the semi-insulting portion of the back-plate has an area larger than or equal to an area of the lateral semiconductor power device chip, and has a thickness that extends to a bottom of the packaged semiconductor device.

5. The packaged semiconductor device of claim 1, wherein respective electrical connections between the at least first and second electrodes and at least one metal lead and the metal portion of the back-plate are established by bond wires.

6. The packaged semiconductor device of claim 1, wherein: the lateral semiconductor power device chip is a field-effect transistor (FET); wherein the first electrode is a gate electrode and is electrically connected to a first metal lead; wherein the second electrode is a source electrode and is electrically connected to the metal portion of the back-plate; wherein a third electrode is a drain electrode and is electrically connected to a second metal lead.

7. The packaged semiconductor device of claim 1, wherein: the lateral semiconductor power device chip is a FET; wherein the first electrode is a gate electrode and is electrically connected to a first metal lead; wherein the second electrode is a drain electrode and is electrically connected to the metal portion of the back-plate; wherein a third electrode is a source electrode and is electrically connected to a second metal lead.

8. The packaged semiconductor device of claim 1, wherein: the lateral semiconductor power device chip comprises a GaN, GaN/GaN, GaN/Si, or GaN/ceramic technology.

9. The packaged semiconductor device of claim 1, wherein a bottom of semiconductor power device chip is implanted for isolation.

10. The packaged semiconductor device of claim 1, wherein the semi-insulating layer is of a property such that a vertical leakage current versus voltage saturates at a voltage greater than 800V.
